(19) United States
(12) Patent Application Publication
(10) Pub. No.: US 2025/0093377 A1
(43) Pub. Date: Mar. 20, 2025

(54) HYBRID ROTATIONAL SPEED DETECTOR

(71) Applicant: ITT Manufacturing Enterprises LLC, Wilmington (DE)

(72) Inventors: Bradley DeCook, Victor, NY (US); James Reitano, Farmington, NY (US)

(21) Appl. No.: 18/724,428

(22) PCT Filed: Dec. 28, 2021
(86) PCT No.: PCT/US2021/065338

§ 371 Date: Jun. 26, 2024

(51) Int. Cl. G01P 3/48

(52) U.S. Cl. CPC G01P 3/48

(57) ABSTRACT

A device to detect a rotational run speed of a piece of rotating machinery. The device includes a processor in communication with a magnetic flux sensor, a vibration sensor, and a memory which includes instructions. The processor is configured to receive magnetic flux data and apply a fast Fourier transform to the magnetic flux data to generate transformed magnetic flux data. The processor is configured to determine a prominent fundamental frequency in the transformed magnetic flux data. For an electrical machine, this prominent fundamental frequency corresponds to the synchronous speed or the speed of the stator magnetic field. The processor is configured to receive vibration data and apply a fast Fourier transform to the vibration data to generate transformed vibration data. The processor is configured to determine an isolated frequency focal band based on the prominent fundamental frequency in the transformed magnetic flux data and to determine the rotational run speed of the piece of rotating machinery based on the isolated frequency focal band and the transformed vibration data. By defining a relatively limited frequency band in which only the vibrational peak corresponding to the true rotational speed of the rotor will be located, it can be avoided to erroneously determine the speed based on a harmonic having a large amplitude.

### TECHNICAL FIELD

The present disclosure generally relates to a rotational speed sensor device used to detect and monitor a rotational speed of a piece of rotating machinery, such as a pump or vibrating machine.

### BACKGROUND

Unless otherwise indicated herein, the materials described in this section are not prior art to the claims in this application and are not admitted being prior art by inclusion in this section.

Rotational speed detector devices may determine a rotational run speed of rotating machinery and may be used to monitor mechanical drive systems and protect elements of a rotational system from mechanical overload. A run speed of rotating machinery may also be used to determine the basis for vibration analysis techniques to monitor machine health. A tachometer is a rotational speed detector device which is wired to a machine to measure a rotational run speed of a shaft or disk of the machine and may display revolutions per minute (RPM) on a dial or digital display. A rotational run speed of a device may also be inferred from a detected vibration with a Fast Fourier transform applied to the detected vibration data in combination with a user input for an estimated or typical machine speed of the device.

### SUMMARY

Existing challenges associated with the foregoing, as well as other challenges, are overcome by the presently disclosed hybrid rotational speed detector and method of wirelessly detecting a rotational speed of a piece of rotating machinery.

One embodiment of the present disclosure is a device to detect a rotational run speed of a piece of rotating machinery. The device includes a magnetic flux sensor, a vibration sensor, a processor, and a memory. The memory includes programmable instructions. The processor is in communication with the magnetic flux sensor, the vibration sensor, and the memory. The processor is configured to receive magnetic flux data from the magnetic flux sensor, and execute the instructions in the memory to, apply a fast Fourier transform to the magnetic flux data to generate transformed magnetic flux data, and determine a prominent fundamental frequency in the transformed magnetic flux data that falls within the typical range of the rotating machinery. The processor is further configured to receive vibration data from the vibration sensor, and execute the instructions in the memory to, apply a fast Fourier transform to the vibration data to generate transformed vibration data, determine an isolated frequency focal band based on the prominent fundamental frequency in the transformed magnetic flux data, and determine the rotational run speed of the piece of rotating machinery based on the isolated frequency focal band and the transformed vibration data.

In aspects, the device is not wired to the piece of rotating machinery.

In aspects, the vibration sensor is or includes an accelerometer.

In aspects, the accelerometer is a piezoelectric a microelectromechanical system (MEMS) accelerometer.

In aspects, the magnetic flux sensor is one of an anisotropic magnetoresistance effect (AMR) magnetometer, a Hall effect sensor, magneto-diode, magneto-transistor, a magnetic tunnel junction magnetometer, a Loentz force based microelectromechanical device (MEMS) sensor, and a fluxgate magnetometer.

In aspects, the prominent fundamental frequency is determined from a peak in the transformed magnetic flux data.

In aspects, processor is further configured to execute instructions in the memory to perform a peak detection algorithm on the transformed magnetic flux data to determine the prominent fundamental frequency that falls within the typical range of the rotating machinery.

In aspects, the rotational run speed of the piece of rotating machinery is determined from a peak in the transformed vibration data that falls within the typical range of the rotating machinery.

In aspects, the processor is further configured to execute instructions in the memory to perform a peak detection algorithm on the transformed vibration data within the isolated frequency focal band to determine the rotational run speed of the piece of rotating machinery.

In aspects, the device further includes a transmitter, and the processor is further configured to send the rotational run speed of the piece of rotating machinery to another device by the transmitter for analytics and machine monitoring.

Another embodiment of the present disclosure includes a method for wirelessly detecting a rotational run speed of a piece of rotating machinery. The method includes a processor receiving magnetic flux data from a magnetic flux sensor, executing instructions in a memory to apply a fast Fourier transform to the magnetic flux data to generate transformed magnetic flux data, and executing instructions in the memory to determine a prominent fundamental frequency in the transformed magnetic flux data that falls within the typical range of the rotating machinery. The method further includes the processor receiving vibration data from a vibration sensor, executing instructions in the memory to apply a fast Fourier transform to the vibration data to generate transformed vibration data, executing instructions in the memory to determine an isolated frequency focal band for the transformed vibration data based on the prominent fundamental frequency in the transformed magnetic flux data, and executing the instructions in the memory to determine the rotational run speed of the piece of rotating machinery based on the isolated frequency focal band and the transformed vibration data.

In aspects, the processor sends the rotational run speed of the piece of rotating machinery to another device for analytics and machine monitoring.

Another embodiment of the present disclosure is a method for wirelessly detecting a rotational run speed of a piece of rotating machinery. The method includes positioning a hybrid rotational detector device proximate to, but not in contact with the piece of rotating machinery. The method further includes a processor of the hybrid rotational detector device receiving magnetic flux data from a magnetic flux sensor of the hybrid rotational detector device, executing instructions in a memory of the hybrid rotational detector device to apply a fast Fourier transform to the magnetic flux data to generate transformed magnetic flux data, and determining a prominent fundamental frequency in the transformed magnetic flux data from a peak in the transformed magnetic flux data that falls within the typical range of the rotating machinery. The method further includes the processor receiving vibration data from a vibration sensor of the hybrid rotational detector device, and executing instructions in the memory to apply a fast Fourier transform to the vibration data to generate transformed vibration data, determine an isolated frequency focal band for the transformed vibration data based on the prominent fundamental frequency in the transformed magnetic flux data, and determine the rotational run speed of the piece of rotating machinery based on the isolated frequency focal band and a peak in the transformed vibration data.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE FIGURES

The foregoing and other features of this disclosure will become more fully apparent from the following description and appended claims, taken in conjunction with the accompanying drawings. Understanding that these drawings depict only several embodiments in accordance with the disclosure and are, therefore, not to be considered limiting of its scope, the disclosure will be described with additional specificity and detail through use of the accompanying drawings, in which:

FIG. 1 is a side view of a hybrid rotational speed detector in accordance with the present disclosure;

FIG. 2A is a graph of fast Fourier transformed magnetic flux data for a rotating machine in accordance with the present disclosure;

FIG. 2B is a graph of fast Fourier transformed vibration data for a rotating machine in accordance with the present disclosure;

FIG. 2C is a graph of fast Fourier transformed vibration data for a rotating machine in accordance with the present disclosure; and

FIG. 3 is a flow diagram of an exemplary process to detect a rotational speed of a piece of rotating machinery in accordance with the present disclosure.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein, and illustrated in the Figures, can be arranged, substituted, combined, separated, and designed in a wide variety of different configurations, all of which are explicitly contemplated herein.

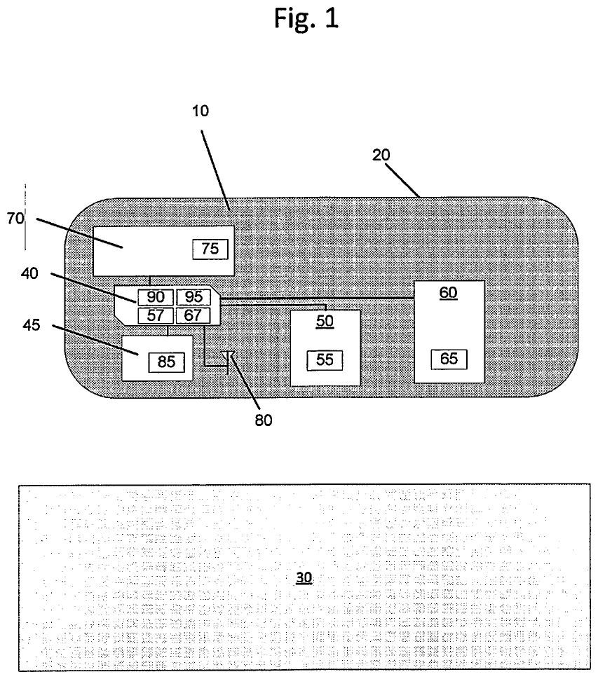

FIG. 1 is a side view of a hybrid rotational speed detector, arranged in accordance with at least some embodiments described herein. A hybrid rotational speed detector device 10 may include a housing 20, a processor 40, a memory 45 storing instructions, a magnetic flux sensor 50, a vibration sensor 60, a display 70, and a transmitter 80. Processor 40 may be in communication with memory 45, magnetic flux sensor 50, vibration sensor 60, display 70, and transmitter 80. Memory 45 includes instructions 85.

Hybrid rotational speed detector device 10 may wirelessly determine a rotational speed of a piece of rotating machinery 30. Hybrid rotational speed detector device 10 may be position proximate to, but not in contact with or wired to, rotating machinery 30, so that magnetic flux sensor 50 may detect magnetic flux emitted by rotating machinery 30. Magnetic flux sensor 50 may be a small-scale microelectromechanical system (MEMS) device for detecting and measuring magnetic fields, an anisotropic magnetoresistance effect (AMR) magnetometer, a Hall effect sensor, magneto-diode, magneto-transistor, a magnetic tunnel junction magnetometer, a Loentz force based microelectromechanical device (MEMS) sensor, or a fluxgate magnetometer. In response to detecting magnetic flux emitted by rotating machinery 30, magnetic flux detector may output magnetic flux data 55.

Vibration sensor 60 may wirelessly detect vibration emitted by rotating machinery 30 and output vibration data 65. Vibration detected by vibration sensor 60 may be a vibration of rotating machinery 30. Vibration sensor 60 may be or include an accelerometer. Vibration sensor 60 may be a piezoelectric microelectromechanical system (MEMS) accelerometer. Processor 40 of hybrid rotational speed detector device 10 may receive magnetic flux data 55 and vibration data 65. As described in more detail below, processor 40 of hybrid rotational speed detector device 10 may execute instructions 85 in memory 45 to wirelessly determine a run speed 75 of rotating machinery 30 based on magnetic flux data 55 and vibration data 65.

Processor 40 of hybrid rotational speed detector device 10 may execute instructions 85 in memory 45 to apply a Fourier transform to magnetic flux data 55 to generate transformed magnetic flux data 57. Processor 40 applying a Fourier transform to magnetic flux data 55 may transform a signal in magnetic flux data 55 into its constituent components and frequencies as transformed magnetic flux data 57. Processor 40 may execute instructions 85 in memory 45 to determine a prominent fundamental frequency 90 in transformed magnetic flux data 57 that falls within the typical range of rotating machinery. Prominent fundamental frequency 90 may be determined as a peak value of transformed magnetic flux data 57 within a graph of transformed magnetic flux data 57 within the typical range of rotating machinery. In some examples, a typical frequency range of rotating machinery may be 180-7200 rpm but may be expanded based on the equipment type. Processor 40 may execute instructions in memory 45 to perform a peak detection algorithm on transformed magnetic flux data 57 to determine prominent fundamental frequency 90.

Processor 40 may execute instructions 85 in memory 45 to apply a Fourier transform to vibration data 65 to generate transformed vibration data 67. Processor 40 applying a Fourier transform to vibration data 65 may transform a signal in vibration data 65 into its constituent components and frequencies as transformed vibration data 67.

Processor 40 may execute instructions 85 to determine an isolated frequency focal band 95 for the transformed vibration data. Isolated frequency focal band 95 may be determined by processor 40 based on a focal band of frequencies around prominent fundamental frequency 90 in transformed magnetic flux data 57. Isolated frequency focal band 95 may be determined by processor 40 based on a typical slip speed for the rotary machine where slip speed is the delta between synchronous speed and run speed of the rotary machine. Processor 40 may execute instructions 85 to determine a synchronous speed as the prominent fundamental frequency 90 found in transformed magnetic flux data 57 and processor 40 may determine a rotational run speed 75 as being about 0.8-1.0 of the determined synchronous speed.

Processor 40 may execute instructions 85 in memory 45 to determine rotational run speed 75 of piece of rotating machinery 30 based on isolated frequency focal band 95 and transformed vibration data 67 within isolated frequency focal band 95. Rotational run speed 75 of piece of rotating machinery 30 may be determined as a peak in a graph of transformed vibration data 67 within isolated frequency focal band 95. Processor 40 may execute instructions in memory 45 to perform a peak detection algorithm on transformed vibration data 67 within isolated frequency focal band 95 to determine rotational run speed 75 of piece of rotating machinery 30. Processor may display rotational run speed 75 on display 70 and/or transmit rotational run speed 75 to another device by transmitter 80 for analytics and machine monitoring.

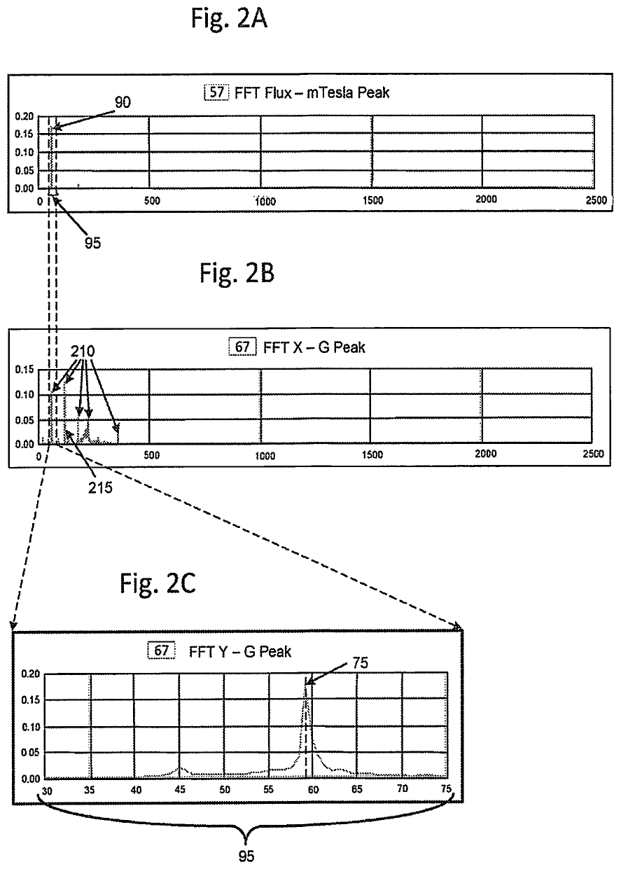

FIG. 2A is a graph of fast Fourier transformed magnetic flux data for a rotating machine, in accordance with the present disclosure and arranged in accordance with at least some embodiments described herein. Those components in FIG. 2A that are labeled identically to components of FIG. 1 will not be described again for the purposes of brevity.

FIG. 2A depicts a graph of fast Fourier transformed magnetic flux data for a rotating machine such as rotating machinery 30 of FIG. 1. The fast Fourier transformed magnetic flux data shown in FIG. 2A may be transformed magnetic flux data 57 that is derived from applying a fast Fourier transform to magnetic flux data 55 from FIG. 1. Transformed magnetic flux data 57 is shown on the y-axis and frequency in hertz (Hz) is shown on the x-axis. As shown in FIG. 2A, a prominent fundamental frequency 200 may be found at a peak in fast Fourier transformed magnetic data 57 at about 60 Hz.

FIG. 2B is a graph of fast Fourier transformed vibration data for a rotating machine in accordance with the present disclosure and arranged in accordance with at least some embodiments described herein. Those components in FIG. 2B that are labeled identically to components of FIG. 1-2A will not be described again for the purposes of brevity.

FIG. 2B depicts a graphical representation for fast Fourier transformed vibration data for a rotating machine such as rotating machinery 30 of FIG. 1. The fast Fourier transformed vibration data shown in FIG. 2B may be transformed vibration data 67 that is derived from applying a fast Fourier transform to vibration data 65 from FIG. 1. Transformed vibration data 67 is shown on the y-axis and frequency in hertz (Hz) is shown on the x-axis. As shown in FIG. 2B, multiple frequency peaks 210 may be found within transformed vibration data 67 with a prominent fundamental frequency 215 found at about 120 Hz.

FIG. 2C is a graph of fast Fourier transformed vibration data for a rotating machine in accordance with the present disclosure and arranged in accordance with at least some embodiments described herein. Those components in FIG. 2C that are labeled identically to components of FIG. 1-2B will not be described again for the purposes of brevity.

FIG. 2C depicts a graphical representation of an isolated frequency focal band for fast Fourier transformed vibration data. As shown above, processor 40 of FIG. 1 may execute instructions 85 to determine an isolated frequency focal band 95 or range of frequency base on prominent fundamental frequency 90 found within the transformed magnetic flux data 57. For example, isolated frequency focal band 95 as shown in FIG. 2C may be determined by processor 40 of FIG. 1 executing instructions 85 to be a range from about 30 Hz to about 75 Hz based on prominent fundamental frequency 90 of about 60 Hz. Processor 40 of FIG. 1 may execute instructions 85 to determine a rotational run speed 75 of piece of rotating machinery 30 based on isolated frequency focal band 220 and vibration data 65. As shown in FIG. 2C, rotational run speed 75 may be about 59 Hz.

A device in accordance with the present disclosure may provide a rotational speed of a piece of rotating machinery without requiring installation of components onto moving parts of the piece of equipment. A device in accordance with the present disclosure may provide a rotational speed of a piece of rotating machinery wirelessly. A device in accordance with the present disclosure may provide actual run speed, slip speed, and allow for calculation of load for a piece of rotating machinery on the fly. A device in accordance with the present disclosure may provide a rotational speed of a piece of rotating machinery without no installation required beyond external mounting of the device. A device in accordance with the present disclosure may provide a rotational speed of a piece of rotating machinery that can account for variable run speed on the fly without user input for each set point. A device in accordance with the present disclosure may provide a more accurate rotational speed of a piece of rotating machinery for more accurate analytics. A device in accordance with the present disclosure may provide a rotational speed of a piece of rotating machinery and be able to account for variable speed drives. A device in accordance with the present disclosure may provide a rotational speed of a piece of rotating machinery which may be stored and collected so users may retrieve the history and historical trends of run speed for a piece of rotary machinery.

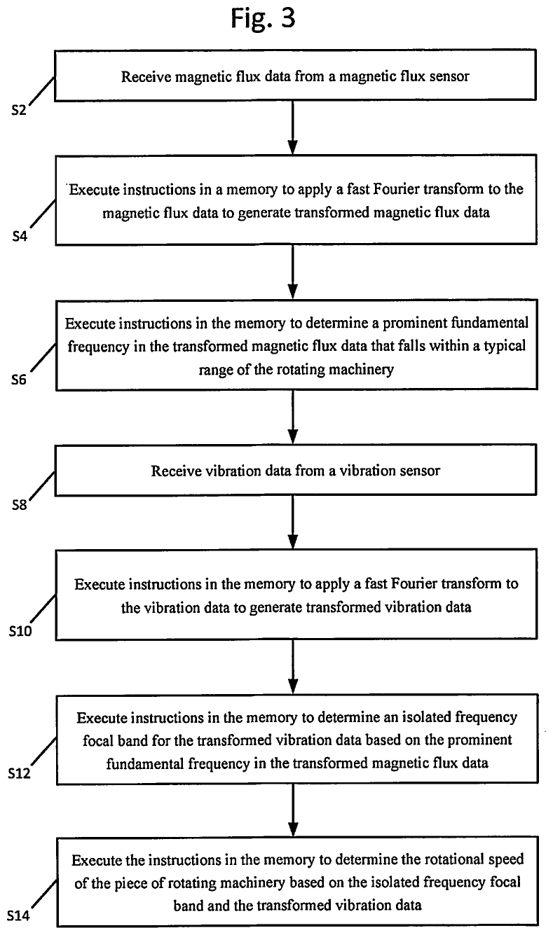

FIG. 3 illustrates a flow diagram for an exemplary process to mount a device that includes a rigid mounting connector, arranged in accordance with at least some embodiments presented herein. An exemplary process may include one or more operations, actions, or functions as illustrated by one or more of blocks S2, S4, S6, S8, S10, S14 and/or S14. Although illustrated as discrete blocks, various blocks may be divided into additional blocks, combined into fewer blocks, or eliminated, depending on the desired implementation.

Processing may begin at block S2, “Receive magnetic flux data from a magnetic flux sensor.” At block S2, a processor of a device for detecting a rotational speed of a piece of rotating machinery may receive magnetic flux data from a magnetic flux sensor. The magnetic flux sensor may be part of the device for detecting a rotational speed of a piece of rotating machinery and may detect magnetic flux emitted by the piece of rotating machinery.

Processing may continue from block S2 to block S4, “Execute instructions in a memory to apply a fast Fourier transform to the magnetic flux data to generate transformed magnetic flux data.” At block S4, the processor may execute instructions to apply a Fourier transform to the magnetic flux data to generate transformed magnetic flux data. Applying a Fourier transform to the magnetic flux data may transform a signal in magnetic flux data into its constituent components and frequencies as transformed magnetic flux data. The instructions may be stored in a memory that the processor is in communication with.

Processing may continue from block S4 to block S6, “Execute instructions in the memory to determine a prominent fundamental frequency in the transformed magnetic flux data that falls within a typical range of the rotating machinery.” At block S6, the processor may execute instructions in the memory to determine a prominent fundamental frequency in the transformed magnetic flux data that falls within a typical range of the rotating machinery. The prominent fundamental frequency of the transformed magnetic flux data may be determined as a peak value of the transformed magnetic flux data within a graph of transformed magnetic flux data. The fundamental frequency may be the synchronous speed or magnetic field speed of the rotating machinery.

Processing may continue from block S6 to block S8, “Receive vibration data from a vibration sensor.” At block S8, the processor may receive vibration data from a vibration sensor. The vibration sensor may be part of the device for detecting a rotational speed of a piece of rotating machinery and may wirelessly detect vibration emitted by piece of equipment. The vibration detected by the vibration sensor may be a vibration of entire piece of equipment. The vibration sensor may be an accelerometer, such as a piezoelectric microelectromechanical system (MEMS) accelerometer.

Processing may continue from block S8 to block S10, “Execute instructions in the memory to apply a fast Fourier transform to the vibration data to generate transformed vibration data.” At block S10, the processor may execute instructions in the memory to apply a fast Fourier transform to the vibration data to generate transformed vibration data. Applying a Fourier transform to the vibration data may transform a signal in the vibration data into its constituent components and frequencies as transformed vibration data.

Processing may continue from block S10 to block S12, “Execute instructions in the memory to determine an isolated frequency focal band for the transformed vibration data based on the prominent fundamental frequency in the transformed magnetic flux data.” At block S12, the processor may execute instructions in the memory to determine an isolated frequency focal band for the transformed vibration data. The isolated frequency focal band may be determined based on a focal band around the prominent fundamental frequency in the transformed magnetic flux data. The isolated frequency focal band may be determined by a typical slip speed associated with rotating machinery, for example, a typical slip speed may be about 0.8-1.0× the synchronous speed or prominent fundamental frequency in the transformed magnetic flux data.

Processing may continue from block S12 to block S14, “Execute the instructions in the memory to determine the rotational speed of the piece of rotating machinery based on the isolated frequency focal band and the transformed vibration data.” At block S14, the processor may execute the instructions in the memory to determine the rotational speed of the piece of equipment. The rotational speed of the piece of rotating machinery may be based on the isolated frequency focal band and the transformed vibration data. The rotational speed of the piece of rotating machinery may be determined as a peak in a graph of transformed vibration data within the isolated frequency focal band.

Finally, the processes and techniques described herein are not inherently related to any particular apparatus and may be implemented by any suitable combination of components. Further, various types of general-purpose devices may be used in accordance with the teachings described herein. It may also prove advantageous to construct specialized apparatus to perform the method steps described herein. This disclosure has been described in relation to the examples, which are intended in all respects to be illustrative rather than restrictive.

The computer-readable storage medium or memory 45 may be a volatile type of memory, e.g., RAM, or a non-volatile type of memory, e.g., flash media, disk media, etc. In various aspects of the disclosure, the processor 40 may be, without limitation, a digital signal processor, a microprocessor, an ASIC, a graphics processing unit (GPU), a field-programmable gate array (FPGA), or a central processing unit (CPU).

It should be understood that the foregoing description is only illustrative of the present disclosure. Various alternatives and modifications can be devised by those skilled in the art without departing from the disclosure. Accordingly, the present disclosure is intended to embrace all such alternatives, modifications, and variances. The embodiments described with reference to the attached drawing figures are presented only to demonstrate certain examples of the disclosure. Other elements, steps, methods, and techniques that are insubstantially different from those described above and/or in the appended claims are also intended to be within the scope of the disclosure.

What is claimed is:

1. A device to detect a rotational run speed of a piece of rotating machinery, the device comprising:
a magnetic flux sensor;
a vibration sensor;
a processor; and
a memory, wherein the memory includes instructions;
wherein the processor is in communication with the magnetic flux sensor, the vibration sensor, and the memory, and the processor is configured to:
receive magnetic flux data from the magnetic flux sensor;
execute the instructions in the memory to apply a fast Fourier transform to the magnetic flux data to generate transformed magnetic flux data;
execute the instructions in the memory to determine a prominent fundamental frequency in the transformed magnetic flux data that falls within a typical range of the rotating machinery;
receive vibration data from the vibration sensor;
execute the instructions in the memory to apply a fast Fourier transform to the vibration data to generate transformed vibration data;
execute the instructions in the memory to determine an isolated frequency focal band based on the prominent fundamental frequency in the transformed magnetic flux data; and
execute the instructions in the memory to determine the rotational run speed of the piece of rotating machinery based on the isolated frequency focal band and the transformed vibration data.

2. The device of claim 1, wherein the device is not wired to the piece of rotating machinery.

3. The device of claim 1, wherein the vibration sensor includes or is an accelerometer.

4. The device of claim 3, wherein the accelerometer is a piezoelectric or a microelectromechanical system (MEMS) accelerometer.

5. The device of claim 1, wherein the magnetic flux sensor is one of an anisotropic magnetoresistance effect (AMR) magnetometer, a Hall effect sensor, magneto-diode, magneto-transistor, a magnetic tunnel junction magnetometer, a Loentz force based microelectromechanical device (MEMS) sensor, and a fluxgate magnetometer.

6. The device of claim 1, wherein the prominent fundamental frequency is determined from a peak in the transformed magnetic flux data that falls within the typical range of the rotating machinery.

7. The device of claim 6, wherein the processor is further configured to execute instructions in the memory to perform a peak detection algorithm on the transformed magnetic flux data to determine the prominent fundamental frequency that falls within the typical range of the rotating machinery.

8. The device of claim 1, wherein the rotational run speed of the piece of rotating machinery is determined from a peak in the transformed vibration data.

9. The device of claim 8, wherein the processor is further configured to execute instructions in the memory to perform a peak detection algorithm on the transformed vibration data within the isolated frequency focal band to determine the rotational run speed of the piece of rotating machinery.

10. The device of claim 1, wherein the device further comprises a transmitter, and the processor is further configured to send the rotational run speed of the piece of rotating machinery to another device by the transmitter for analytics and machine monitoring.

11. A method for wirelessly detecting a rotational run speed of a piece of rotating machinery, the method comprising a processor:
receiving magnetic flux data from a magnetic flux sensor;
executing instructions in a memory to apply a fast Fourier transform to the magnetic flux data to generate transformed magnetic flux data;
executing instructions in the memory to determine a prominent fundamental frequency in the transformed magnetic flux data that falls within a typical range of the rotating machinery;
receiving vibration data from a vibration sensor;
executing instructions in the memory to apply a fast Fourier transform to the vibration data to generate transformed vibration data;
executing instructions in the memory to determine an isolated frequency focal band for the transformed vibration data based on the prominent fundamental frequency in the transformed magnetic flux data; and
executing the instructions in the memory to determine the rotational run speed of the piece of rotating machinery based on the isolated frequency focal band and the transformed vibration data.

12. The method of claim 11, further comprising determining the prominent fundamental frequency from a peak in the transformed magnetic flux data that falls within the typical range of the rotating machinery.

13. The method of claim 12, further comprising executing instructions in the memory to perform a peak detection algorithm on the transformed magnetic flux data to determine the prominent fundamental frequency that falls within the typical range of the rotating machinery.

14. The method of claim 11, further comprising determining the rotational run speed of the piece of rotating machinery from a peak in the transformed vibration data.

15. The method of claim 14, further comprising executing instructions in the memory to perform a peak detection algorithm on the transformed vibration data within the isolated frequency focal band to determine the rotational run speed of the piece of equipment.

16. The method of claim 11, wherein the processor is part of a hybrid rotational detector device, the method further comprising positioning the hybrid rotational detector device proximate to, but not in contact with, the piece of rotating machinery.

17. The method of claim 11, further comprising the processor sending the rotational run speed of the piece of rotating machinery to another device for analytics and machine monitoring.

18. A method for wirelessly detecting a rotational run speed of a piece of rotating machinery, the method comprising:
positioning a hybrid rotational detector device proximate to, but not in contact with the piece of rotating machinery;
the method further comprising, by a processor of the hybrid rotational detector device:
receiving magnetic flux data from a magnetic flux sensor of the hybrid rotational detector device;
executing instructions in a memory of the hybrid rotational detector device to apply a fast Fourier transform to the magnetic flux data to generate transformed magnetic flux data;
executing instructions in the memory to determine a prominent fundamental frequency in the transformed magnetic flux data from a peak in the transformed magnetic flux data that falls within a typical range of the rotating machinery;
receiving vibration data from a vibration sensor of the hybrid rotational detector device;
executing instructions in the memory to apply a fast Fourier transform to the vibration data to generate transformed vibration data;
executing instructions in the memory to determine an isolated frequency focal band for the transformed vibration data based on the prominent fundamental frequency in the transformed magnetic flux data; and
executing the instructions in the memory to determine the rotational run speed of the piece of rotating machinery based on the isolated frequency focal band and a peak in the transformed vibration data.

19. The method of claim 18, further comprising executing instructions in the memory to perform a peak detection algorithm on the transformed magnetic flux data to determine the prominent fundamental frequency that falls within the typical range of the rotating machinery.

20. The method of claim 18, further comprising executing instructions in the memory to perform a peak detection algorithm on the transformed vibration data within the isolated frequency focal band to determine the rotational run speed of the piece of rotating machinery.
